(19) United States
(12) Patent Application Publication
(10) Pub. No.: US 2011/0115334 A1
(43) Pub. Date: May 19, 2011

(54) SURFACE ACOUSTIC WAVE ELEMENT

(75) Inventors: Yoshiyuki KONISHI, Nagaokakyo-shi (JP); Shinichi FUKUDA, Nagaokakyo-shi (JP)

(73) Assignee: MURATA MANUFACTURING CO., LTD., Nagaokakyo-shi (JP)

(21) Appl. No.: 12/945,960

(22) Filed: Nov. 15, 2010

(30) Foreign Application Priority Data
Nov. 16, 2009 (JP) 2009-260821

(51) Int. Cl. H01L 41/047

(52) U.S. Cl. 310/313 B

(57) ABSTRACT

A surface acoustic wave element includes a piezoelectric substrate made of a LiNbO₃ or LiTaO₃ single crystal, a base electrode layer disposed on the piezoelectric substrate and primarily including at least one of Ti and Cr, and an Al electrode layer primarily including Al disposed on the base electrode layer. The Al electrode layer is an epitaxially grown film with an orientation, and has a twin crystal structure exhibiting six-fold symmetry spots in an XRD pole figure. The average grain size of the Al electrode layer is about 60 nm or less.

### BACKGROUND OF THE INVENTION

1. Field of the Invention

The present invention relates to surface acoustic wave elements, and particularly, to a surface acoustic wave element including an electrode layer primarily including Al and having a twin crystal structure.

2. Description of the Related Art

The surface acoustic wave element is an electronic component using surface acoustic waves that propagate mechanical vibration energy. The surface acoustic wave element typically includes a piezoelectric substrate, and an interdigital transducer (IDT electrode) on the piezoelectric substrate through which a signal is applied to or extracted from the surface acoustic wave element.

The IDT electrode is typically made of a material having a low electrical resistivity and a low specific gravity, such as Al or an Al-based alloy. Unfortunately, Al has a low electrical power handling capability. If a high power is applied to the Al electrode, a hillock or a void may be produced in the electrode. The hillock or the void may cause short-circuiting of the electrode and result in destruction of the surface acoustic wave element.

Japanese Unexamined Patent Application Publication No. 2002-305425 discloses a surface acoustic wave element having an increased electrical power handling capability by epitaxially growing Al into a twin crystal structure such that the crystal orientation is aligned in a predetermined direction. Japanese Unexamined Patent Application Publication No. 8-148966 discloses a surface acoustic wave element having an increased electrical power handling capability by specifying the ratio of the crystal grain size of an Al-based electrode film to the standard deviation of the grain size or the thickness of the electrode film.

However, the electrical power handling capability of the surface acoustic wave elements described above are insufficient for use in high-frequency applications and high-power applications.

### SUMMARY OF THE INVENTION

To overcome the problems described above, preferred embodiments of the present invention provide a surface acoustic wave element having a high electrical power handling capability.

The inventors of the present invention discovered that when the Al electrode layer has an average crystal grain size of about 60 nm or less, the electrical power handling capability of the surface acoustic wave element is dramatically increased.

According to a preferred embodiment of the present invention, a surface acoustic wave element is provided which includes a piezoelectric substrate made of a LiNbO₃ or LiTaO₃ single crystal, a base electrode layer disposed on the piezoelectric substrate and primarily including at least one of Ti and Cr, and an Al electrode layer primarily including Al disposed on the base electrode layer. The Al electrode layer is an epitaxially grown film having an orientation and a twin crystal structure exhibiting six-fold symmetry spots in an X-ray diffraction (XRD) pole figure. The average grain size of the Al electrode layer is preferably about 60 nm or less, for example.

Preferably, the average grain size of the Al electrode layer is about 0.2864 nm or greater, for example.

Preferably, the average grain size of the Al electrode layer is in the range of about 42 nm to about 58 nm, for example.

It is believed that when the Al electrode layer has an average crystal grain size of about 60 nm or less, most of the grain boundaries have twin crystal structures with atomic level widths. Accordingly, the activation energy of the Al electrode layer is close to the activation energy in a bulk state, such that the electrical power handling capability can be dramatically increased. Therefore, preferred embodiments of the present invention provide a surface acoustic wave element having a high electrical power handling capability.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a sectional view of a surface acoustic wave element according to a preferred embodiment of the present invention showing main portions thereof.

FIGS. 2A and 2B are exemplary XRD pole figures of an Al electrode layer according to a preferred embodiment of the present invention.

FIG. 3 is a scanning transmission electron micrograph used in an Example of a preferred embodiment of the present invention to calculate an average grain size.

FIG. 4 is a scanning transmission electron micrograph of an Al electrode layer of an Example of a preferred embodiment of the present invention.

### DETAILED DESCRIPTION OF THE PREFERRED EMBODIMENTS

An exemplary preferred embodiment of the invention will now be described.

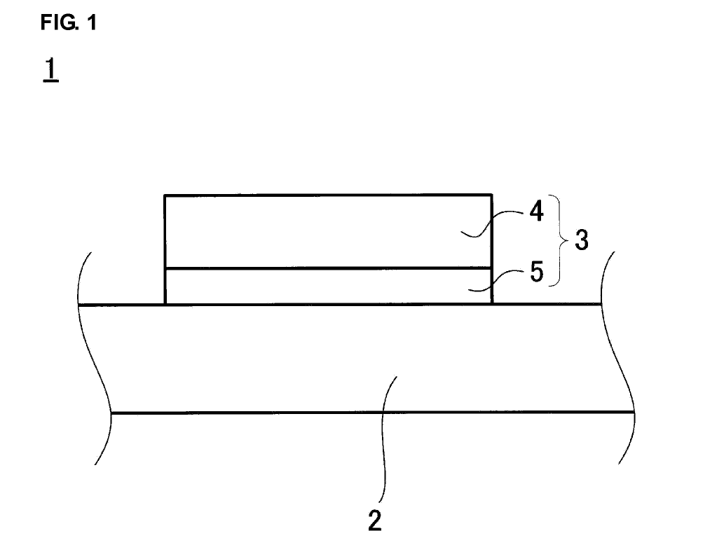

FIG. 1 is a fragmentary sectional view showing main portions of a surface acoustic wave element 1 according to a preferred embodiment of the present invention. FIG. 1 shows a portion in which an electrode 3 is disposed on a piezoelectric substrate 2.

The piezoelectric substrate 2 is preferably made of a LiTaO₃ or LiNbO₃ single crystal, for example. The electrode 3 includes an Al electrode layer 4 and a base electrode layer 5.

The base electrode layer 5 is disposed on the piezoelectric substrate 2. The base electrode layer 5 is provided to improve the adhesion between the piezoelectric substrate 2 and the Al electrode layer 4. The base electrode layer 5 preferably primarily includes at least either Ti or Cr, for example. The Al electrode layer 4 is disposed on the base electrode layer 5. The Al electrode layer 4 preferably includes, for example, Al or an Al-based alloy as the main component.

The surface acoustic wave element 1 may preferably be manufactured with the following process. First, a piezoelectric substrate 2 is prepared. On the piezoelectric substrate 2, a base electrode layer 5 is formed by, for example, vacuum vapor deposition. Subsequently, an Al electrode layer 4 is formed on the base electrode layer 5 by, for example, vacuum vapor deposition. The resulting electrode 3 is formed into a shape of an IDT electrode by photolithography and dry etching, for example.

A damaged layer may be formed to a depth of several nanometers over the surface of the piezoelectric substrate 2 by polishing or other processing, for example. This layer may hinder epitaxial growth. Accordingly, before forming the base electrode layer 5, the damaged layer may preferably be removed to expose a crystal face at the surface of the piezoelectric substrate 2. Thus, a crystal face allowing epitaxial growth can be exposed at the surface of the piezoelectric substrate 2.

For forming the base electrode layer 5 and the Al electrode layer 4, first, the base electrode layer 5 is preferably formed, for example, by heating deposition at a temperature of about 150° C. or greater and at a rate of about 0.5 nm/s or less, for example. With this heating deposition of the base electrode layer 5, an energy required for crystal growth is applied to the piezoelectric substrate 2, such that the resulting base electrode layer 5 has an orientation corresponding to the crystal orientation of the piezoelectric substrate 2. Then, the Al electrode layer 4 is preferably formed, for example, by low-temperature deposition at a temperature of about 75° C. or less and at a rate of about 3.5 nm/s or less, for example. Thus, an epitaxially grown, oriented film having a twin crystal structure is formed as the Al electrode layer 4.

For the deposition of the base electrode layer 5, as the deposition temperature increases, the crystallinity of the base electrode layer 5 is improved. However, an excessively high deposition temperature may result in cracks in the piezoelectric substrate 2 due to pyroelectricity. Preferably, the deposition temperature for the base electrode layer 5 is about 300° C. or less, for example.

For the deposition of the Al electrode layer 4, when the deposition temperature is less than about 0° C., the cooling is performed in a special manner, and the cost is increased accordingly. Preferably, the deposition of the Al electrode layer 4 is performed at a temperature of about 0° C. or greater, for example.

The crystal grain size of the Al electrode layer 4 depends upon the deposition temperature and the deposition rate. The crystal grain size of the Al electrode layer is reduced as the deposition temperature is reduced. In addition, when the base electrode layer 5 is formed at a deposition rate of about 0.5 nm/s or less and when the Al electrode layer 4 is formed at a deposition rate of about 3.5 nm/s or less, for example, the crystallinity of the resulting layers is improved, such that dense layers can be formed. Thus, the electrical power handling capability can be increased by optimizing both the deposition temperature and the deposition rate.

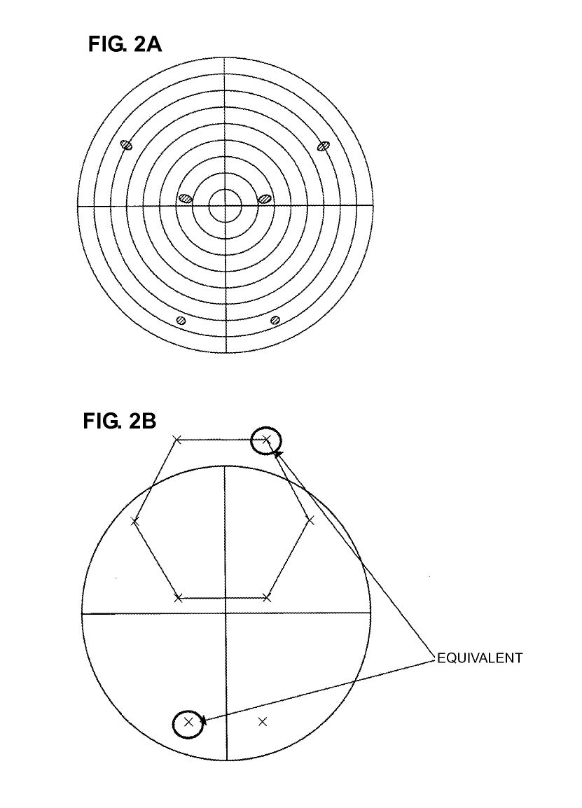

The twin crystal structure refers to a structure exhibiting six symmetrical spots in an XRD pole figure. FIGS. 2A and 2B are exemplary XRD pole figures of the Al electrode layer of the present preferred embodiment. FIG. 2A is an XRD pole figure, and FIG. 2B schematically shows the figure of FIG. 2A. These figures were obtained by a reflection from an Al (200) plane. The six symmetrical detection points of the reflection signal from the Al (200) plane shown in FIG. 2A suggest that the Al crystal has a twin crystal structure having two orientations rotated by about 180°.

The deposition temperature for the base electrode layer 5 may preferably be changed to about 75° C. or less, for example, in the course of the deposition, and the deposition is continued at about 75° C. or less to form the base electrode layer. The Al electrode layer is subsequently formed at that temperature without changing the deposition temperature. In this case, it is unlikely that an oxide layer is formed at the interface between the base electrode layer and the Al electrode layer. Accordingly, the crystallinity of the Al electrode layer can be improved.

The following mechanism is believed to be the reason why the electrical power handling capability of the surface acoustic wave element is dramatically increased when the Al electrode layer 4 has an average crystal grain size of about 60 nm or less. It is believed that when the average crystal grain size is about 60 nm or less, small crystal grains grow densely to form the Al electrode layer, such that most of the grain boundaries have a twin crystal structure and have atomic level widths. The activation energy of such a layer is estimated to be close to the activation energy in a bulk state (about 135.1 kJ/mol at about 100° C.), and the electrical power handling capability can be dramatically increased. The presence of many twin crystal structures does not easily enable plastic deformation, can lead a problem of electrode fractures caused by stress migration. Consequently, the electrical power handling capability can be increased.

In contrast, crystal grains having an average grain size of about 60 nm or greater include not only atomic level twin boundaries, but also ordinary grain boundaries. The activation energy of such a film is dominated by the activation energy (about 38.6 kJ/mol at about 100° C.) of the crystal grain boundaries. Therefore, it is believed that the activation energy is reduced so as to reduce the electrical power handling capability.

If an Al electrode layer is formed so as to have an average crystal grain size equal or substantially equal to the minimum interatomic spacing of aluminum, about 0.2864 nm, then the resulting Al electrode layer is in a bulk state, and the electrical power handling capability can be increased to the greatest extent. However, it is theoretically difficult to reduce the average grain size to less than about 0.2864 nm. The average grain size is preferably set to about 0.2864 nm or greater, for example.

For experimental examples, surface acoustic wave filters including a surface acoustic wave element having the structure shown in FIG. 1 were prepared. Surface acoustic wave filters of Examples 1 to 3 and Comparative Examples 1 to 7 were prepared so that the Al electrodes have different crystal grain sizes in a process in which the electrodes were formed at different temperatures in two stages.

First, a piezoelectric substrate 2 made of 42° Y-cut LiTaO₃ single crystal was prepared.

Then, a Ti base electrode layer was formed to a thickness of about 10 nm on the piezoelectric substrate by electron beam vacuum vapor deposition at a first temperature. The resulting structure was cooled to the second temperature in a vacuum. Then, the base electrode layer was further formed to an overall thickness of about 20 nm at a second temperature. Subsequently, an Al electrode layer was formed to a thickness of about 120 nm at the second temperature. In this process, Ti was deposited at a rate of about 0.1 nm/s, and Al was deposited at a rate of about 2.0 nm/s. The resulting electrode was formed into an IDT electrode by photolithography and dry etching.

A connection pad arranged to establish an electrical connection with an external wiring board and a wiring pattern arranged to connect the connection pad to the Al electrode layer were formed on the piezoelectric substrate. For forming the wiring pattern, a Ti layer was formed to a thickness of about 200 nm on the piezoelectric substrate, and an Al layer was formed to a thickness of about 1140 nm on the Ti layer. The connection pad and the wiring pattern were formed by vacuum vapor deposition in the same manner as the electrode.

The table below shows the average crystal grain sizes and the electrical power handling times of the surface acoustic wave filters of the Examples and Comparative Examples that were prepared in the process in which the first temperature and the second temperature differed.

TABLE

| | 1st | 2nd | Average | Electric power |
|---|---|---|---|---|
| | Temperature | Temperature | grain size | handling time |
| | (° C.) | (° C.) | (nm) | (h) |
| Example 1 | 165 | 75 | 42 | 15000 |
| Example 2 | 160 | 75 | 43 | 18500 |
| Example 3 | 150 | 75 | 58 | 15000 |
| Comparative | 140 | 75 | 75 | 470 |
| Example 1 | | | | |
| Comparative | 140 | 80 | 62 | 2271 |
| Example 2 | | | | |
| Comparative | 140 | 100 | 109 | 249 |
| Example 3 | | | | |
| Comparative | 140 | 139 | 90 | 45 |
| Example 4 | | | | |
| Comparative | 130 | 75 | 92 | 274 |
| Example 5 | | | | |
| Comparative | 155 | 105 | 75 | 6154 |
| Example 6 | | | | |
| Comparative | 145 | 65 | 86 | 4035 |
| Example 7 | | | | |

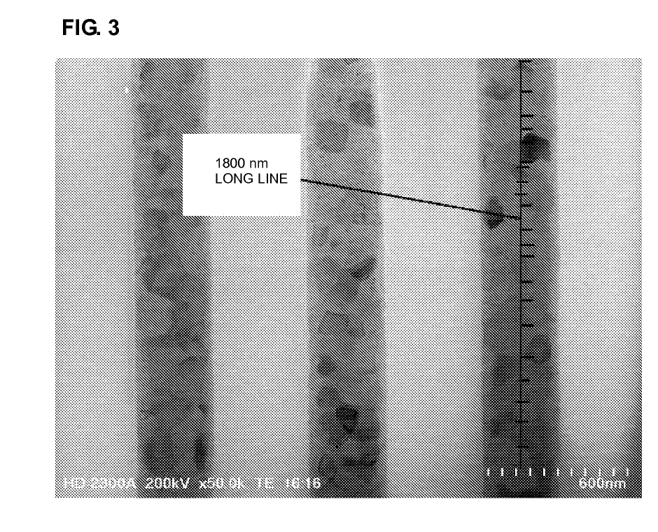

FIG. 3 shows a micrograph used to calculate the average grain size of the Al electrode layer. Lines shown in FIG. 3 represent the positions of grain boundaries. The average grain size was measured as described below. First, the IDT electrode was formed, and was then sliced in the direction parallel or substantially parallel to the main surface of the piezoelectric substrate. The sliced section of the IDT electrode was observed through a scanning transmission electron microscope having a magnification of 50,000 times. In the micrograph, a straight line of about 1800 nm in length was drawn parallel to the fingers of the IDT electrode, and the number of grain boundaries intersecting with the straight line was counted. The average grain size was calculated from the following equation (A):

Average grain size=length of straight line/number of grain boundaries (A)

The electric power handling time was calculated from the measurements below. The lifetime measurements were performed on the surface acoustic wave filters of the examples and comparative examples at a power of about 0.8 W and a temperature of about 120° C. The measured lifetime was converted into a lifetime at the specification electrical power of about 0.5 W and the specification temperature of about 85° C.

In Examples 1 to 3, in which the electrode was formed at a first temperature of about 150° C. or more and a second temperature of about 75° C. or less, the average grain sizes were about 42 nm to about 58 μm, and the electrical power handling times were about 15,000 hours or more. On the other hand, Comparative Examples 1 to 5 and 7, in which the electrode was formed at a first temperature of less than about 150° C., had average grain sizes of about 62 nm to about 109 μm and electrical power handling times of less than about 5,000 hours. In Example 6, in which the electrode was formed at a first temperature of about 155° C. and a second temperature of about 105° C., the electrical power handling time was about 6154 hours, which is significantly less than that of Examples 1 to 3.

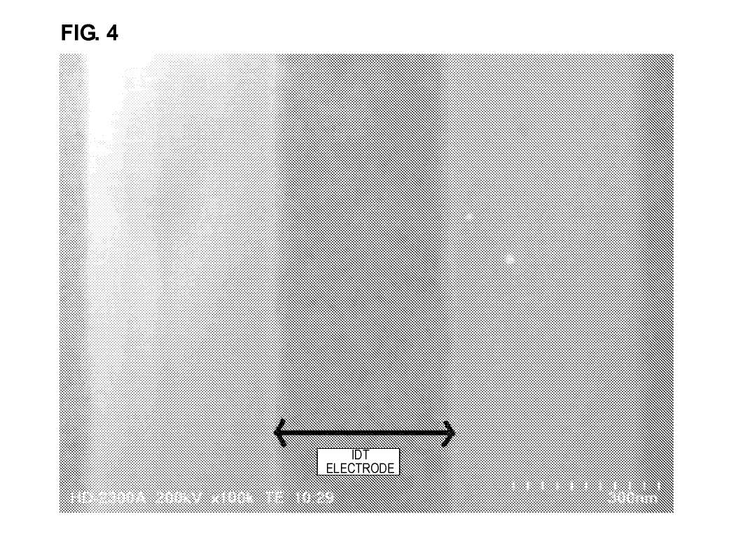

FIG. 4 is a scanning transmission electron micrograph of the Al electrode layer of Example 1. The grain boundaries in this figure are indistinct. This suggests that small grains were densely grown. If such an Al electrode layer is formed, the electrical power handling capability can be significantly increased.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A surface acoustic wave element comprising:
a piezoelectric substrate made of a LiNbO₃ or LiTaO₃ single crystal;
a base electrode layer disposed on the piezoelectric substrate and primarily including at least one of Ti and Cr; and
an Al electrode layer primarily Al disposed on the base electrode layer, the Al electrode layer being an epitaxially grown film with an orientation, and the Al electrode layer having a twin crystal structure exhibiting six-fold symmetry spots in an XRD pole figure and an average grain size of about 60 nm or less.

2. The surface acoustic wave element according to claim 1, wherein the average grain size is about 0.2864 nm or more.

3. The surface acoustic wave element according to claim 1, wherein the average grain size is about 42 nm to about 58 nm.
